(19) United States
(12) Patent Application Publication
(10) Pub. No.: US 2020/0185467 A1
(43) Pub. Date: Jun. 11, 2020

(54) ACTIVE MATRIX ORGANIC LIGHT-EMITTING DIODE DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Liang SUN, Wuhan, Hubei (CN); Shoucheng Wang, Wuhan, Hubei (CN); Mian Zeng, Wuhan, Hubei (CN); Shijuan YI, Wuhan, Hubei (CN)

(21) Appl. No.: 16/330,091

(22) PCT Filed: Dec. 29, 2018
(86) PCT No.: PCT/CN2018/125210

§ 371 Date: Mar. 3, 2019

(30) Foreign Application Priority Data
Dec. 6, 2018 (CN) 201811485917.X

(51) Int. Cl. H01L 27/32; H01L 51/52

(52) U.S. Cl. CPC H01L 27/3246; H01L 2227/323; H01L 51/5206; H01L 27/3272

(57) ABSTRACT

An active matrix organic light-emitting diode (AMOLED) display panel is provided. The AMOLED display panel includes a display light-emitting region, a driving circuit region disposed below the display light-emitting region, and a fan-out region. An area of the driving circuit region is less than an area of the display light-emitting region, and the display light-emitting region completely covers the driving circuit region and at least a portion of the fan-out region. The AMOLED display panel saves a certain space for setting traces of the fan-out region by reducing an area of a lower edge region of the driving circuit region, so that a width of a lower side frame of the display panel is reduced.

### BACKGROUND OF INVENTION

### Field of Invention

The present invention relates to a field of display technology, and more particularly, to an active matrix organic light-emitting diode (AMOLED) display panel.

### Description of Prior Art

With the development of display industry technology, people are increasingly demanding high-quality display panels. For some high-end display panels, people will need to obtain narrow frame display panels.

With the development of flexible active matrix organic light-emitting diode (AMOLED) display panels, a new pad bending technology has been proposed for large lower frames of rigid panels. As shown in FIG. 1, a chip on film (COF) is disposed on a bonding pad area (bonding area) or an ultra-thin chip on plastic (COP) is disposed on an IC (integrated circuit) bonding pad area, and both the bonding pad area and the IC bonding pad area are disposed below a display panel. A fanout trace connected to a data signal of a pixel circuit in an active area. The bonding pad area or the IC bonding pad area, the fanout trace, and some test circuit areas are bent below the panel, which can narrow the lower frames of original rigid display panels.

Referring to FIG. 1, it is a schematic view of the existing flexible AMOLED display panel structure. In the existing display panels, in order to ensure a width called E value which is required for the panels having a curved edge, a distance called D value between the active area and a bending area (bending area C2) is still large due to a layout space of a fan-out region C3 (a data line of the active area C1 is fanned into a bending region, so that the E value and the D value are greater). In addition, a space is required for the bending area, so that the lower frame of the entire panel is still large.

As shown in FIG. 2, the flexible AMOLED display panel includes a driving unit 11′ and a display unit 12′. The driving unit 11′ corresponds to the display unit 12′, and the driving unit 11′ and the display unit 12′ have a same size. Also, the driving unit 11′ and the display unit 12′ are disposed in a same area and connected to each other through via holes.

Therefore, it is necessary to provide a narrow frame AMOLED display panel to solve the above technical problems.

### SUMMARY OF INVENTION

One embodiment of the present invention provides a narrow frame AMOLED display panel to solve the technical problem that a large width of lower frame of existing AMOLED display panel.

In one embodiment of the present invention, an active-matrix organic light-emitting diode (AMOLED) display panel comprises a driving circuit region for driving a display light-emitting region to emit light; a fan-out region for setting a fanout trace; and a display light-emitting region disposed above the driving circuit region and the fan-out region; wherein an area of the driving circuit region is less than an area of the display light-emitting region, and the display light-emitting region completely covers the driving circuit region and at least a portion of the fan-out region; the driving circuit region comprises a plurality of driving units, the display light-emitting region comprises a plurality of display units, each of the driving units is electrically connected to one of the display units, and an area of each of the driving units is less than an area of each of the display units; the driving circuit region comprises an intermediate region and a lower edge region disposed below the intermediate region, and a distance between each two of the driving units disposed in the intermediate region is greater than a distance between each two of the driving units disposed in the lower edge region; the display light-emitting region comprises a first display light-emitting region corresponding to the lower edge region and a third display light-emitting region corresponding to the fan-out region, and at least a portion of the driving units is electrically connected to the display units disposed in the third display light-emitting region; and the fan-out region is disposed at one side of the lower edge region, and the fan-out region comprises a first portion covered by the display light-emitting region and a second portion disposed outside the display light-emitting region.

The AMOLED display panel according to one embodiment of the present invention, each of the driving units comprises a driving thin film transistor for driving the display unit to emit light, and the driving thin film transistor comprises a source/drain and a planar layer disposed on the source/drain; each of the display units comprises an anode disposed on the planar layer and a pixel defining layer disposed on the anode, and the pixel defining layer is provided with an opening; the source/drain is electrically connected to the anode; the lower edge region comprises a first edge, and the first edge is disposed at a side of the lower edge region close to the intermediate region; and in one of the driving units disposed in the lower edge region and in one of the display units which is electrically connected to the one of driving units disposed in the lower edge region and located near the first edge, the source/drain of each the driving units is closer to the first edge in relative to the anode of each the display units.

The AMOLED display panel according to one embodiment of the present invention, a distance between the source/drain of each the driving units and the anode in the lower region is larger from a side near the first edge to another side away from the first edge.

The AMOLED display panel according to one embodiment of the present invention, a length of the source/drain of each the driving units electrically connected to the anode of each the display units disposed in the lower edge region is longer from a side near the first edge to another side away from the first edge.

The AMOLED display panel according to one embodiment of the present invention, each of the driving thin film transistors comprises a substrate, an active layer disposed on the substrate, a first gate disposed on the active layer, a second gate disposed on the first gate, the source/drain disposed on the second gate, and the planar layer disposed on the source/drain; and the source/drain of the driving thin film transistor is electrically connected to the anode corresponding to the display unit through a via hole.

The AMOLED display panel according to one embodiment of the present invention, each of the driving thin film transistors comprises a substrate, an active layer disposed on the substrate, a first gate disposed on the active layer, a second gate disposed on the first gate, the source/drain disposed on the second gate, the planar layer disposed on the source/drain, and a source/drain trace disposed on the planar layer; the source/drain of the driving thin film transistor is electrically connected to the anode of the corresponding display unit through the source/drain trace; and a length of the source/drain trace of another one of the driving units electrically connected to the anode of another one of the display units disposed in the lower edge region and away from the first edge is longer than a length of the source/drain trace of the one of the driving units near the first edge.

The AMOLED display panel according to one embodiment of the present invention, the driving circuit region further comprises two side edge regions disposed at both sides of the intermediate region, and a distance between each two of the driving units disposed in the intermediate region is greater than a distance between each two of the driving units disposed at each of the two side edge regions.

In another embodiment of the present invention, an active-matrix organic light-emitting diode (AMOLED) display panel comprises a driving circuit region for driving a display light-emitting region to emit light; a fan-out region for setting a fanout trace; and a display light-emitting region disposed above the driving circuit region and the fan-out region; wherein an area of the driving circuit region is less than an area of the display light-emitting region, and the display light-emitting region completely covers the driving circuit region and at least a portion of the fan-out region.

The AMOLED display panel according to one embodiment of the present invention, the driving circuit region comprises a plurality of driving units, the display light-emitting region comprises a plurality of display units, each of the driving units is electrically connected to one of the display units, and an area of each of the driving units is less than an area of each of the display units.

The driving circuit region comprises an intermediate region and a lower edge region disposed below the intermediate region, and a distance between each two of the driving units disposed in the intermediate region is greater than a distance between each two of the driving units disposed in the lower edge region, so that the area of lower edge of driving region is reduced.

The AMOLED display panel according to one embodiment of the present invention, each of driving units comprises a driving thin film transistor for driving the display unit emitting, and the driving thin film transistor comprises a source/drain and a planar layer disposed on the source/drain; each the display units comprises an anode disposed on the planar layer and a pixel defining layer disposed on the anode, and the pixel defining layer is provided with an opening; the source/drain is electrically connected to the anode; the display light-emitting region comprises a first display light-emitting region corresponding to the lower edge region and a third display light-emitting region corresponding to the fan-out region, and at least portion of the driving units is electrically connected to the display units disposed in the third display light-emitting region.

The AMOLED display panel according to one embodiment of the present invention, the lower edge region comprises a first edge, and the first edge is disposed at a side of the lower edge region close to the intermediate region; and in one of the driving units disposed in the lower edge region and in one of the display units which is electrically connected to the one of driving units disposed in the lower edge region and located near the first edge, the source/drain of each the driving units is closer to the first edge in relative to the anode of each the display units.

The AMOLED display panel according to one embodiment of the present invention, a distance between the source/drain of each the driving units and the anode in the lower edge region is larger from a side near the first edge to another side away from the first edge.

The AMOLED display panel according to one embodiment of the present invention, a length of each the source/drain of the driving units electrically connected to the anode of each the display units disposed in the lower edge region is longer from a side near the first edge to another side away from the first edge.

The AMOLED display panel according to one embodiment of the present invention, the fan-out region is disposed at one side of the lower edge region, and the fan-out region comprises a first portion covered by the display light-emitting region and a second portion disposed outside the display light-emitting region.

The AMOLED display panel according to one embodiment of the present invention, the driving circuit region further comprises an upper edge region disposed above the intermediate region, and a distance between each two of the driving units disposed in the intermediate region is greater than a distance between each two of the driving units disposed at the upper edge region, so that the area of upper edge of driving region is reduced.

The AMOLED display panel according to one embodiment of the present invention, the driving circuit region comprises two side edge regions disposed at both sides of the intermediate region, and a distance between each two of the driving units disposed in the intermediate region is greater than a distance between each two of the driving units disposed at the two side edge regions, so that the area of two side edge of driving regions is reduced.

The AMOLED display panel according to one embodiment of the present invention, the driving circuit region comprises a plurality of driving units, the display light-emitting region comprises a plurality of display units, each of the driving units is electrically connected to one of the display units; and the driving circuit region comprises an intermediate region and a lower edge region disposed below the intermediate region, and an area of each of the driving units disposed in the intermediate region is equal to an area of each of the display units disposed in the intermediate region, and an area of each of the driving units disposed in the lower edge region is less than an area of each of the display units disposed in the lower edge region.

The AMOLED display panel according to one embodiment of the present invention, each of driving units comprises a driving thin film transistor, and the driving thin film transistor comprises a source/drain and a planar layer disposed on the source/drain; each of the display units comprises an anode disposed on the planar layer and a pixel defining layer disposed on the anode, and the pixel defining layer is provided with an opening; the source/drain is electrically connected to the anode; the display light-emitting region comprises a first display light-emitting region corresponding to the lower edge region and a third display light-emitting region corresponding to the fan-out region, and at least portion of the driving units is electrically connected to the display units disposed in the third display light-emitting region.

The AMOLED display panel according to one embodiment of the present invention, the lower edge region comprises a first edge, and the first edge is disposed at a side of the lower edge region close to the intermediate region; and in one of the driving units is disposed in the lower edge region and in one of the display units is electrically connected to the one of driving units disposed in the lower edge region and located near the first edge, the source/drain of each the driving units is closer to the first edge in relative to the anode of each the display units.

The AMOLED display panel according to one embodiment of the present invention, a distance between the source/drain of each the driving units and the anode in the lower edge region is larger from a side near the first edge to another side away from the first edge.

The AMOLED display panel according to one embodiment of the present invention, a length of the source/drain of each the driving units electrically connected to the anode of the display unit disposed in the lower edge region is longer from a side near the first edge to another side away from the first edge.

The AMOLED display panel according to one embodiment of the present invention, the fan-out region is disposed at one side of the lower edge region, and the fan-out region comprises a first portion covered by the display light-emitting region and a second portion disposed outside the display light-emitting region.

The AMOLED display panel according to one embodiment of the present invention, each of the driving thin film transistors comprises a substrate, an active layer disposed on the substrate, a first gate disposed on the active layer, a second gate disposed on the first gate, the source/drain disposed on the second gate, the planar layer disposed on the source/drain, and the source/drain of the driving thin film transistor is electrically connected to the anode of the corresponding display unit through a via hole, and a trace of the fan-out region extends outwardly from a lower edge region of the drive circuit region.

The AMOLED display panel according to one embodiment of the present invention, each of the driving thin film transistors comprises a substrate, an active layer disposed on the substrate, a first gate disposed on the active layer, a second gate disposed on the first gate, the source/drain disposed on the second gate, the planar layer disposed on the source/drain, and a source/drain trace is disposed on the planar layer; the source/drain of the driving thin film transistor is electrically connected to the anode of the corresponding to the display unit through the source/drain trace; and a length of the source/drain trace of another one of the driving units electrically connected to the anode of another one of the display units disposed in the lower edge region and away from the first edge is longer than a length of the source/drain trace of the one of the driving units near the first edge.

In the present invention, it should be noted that, when the pixels per inch (PPI) is less than 530, the area of the driving unit can be less than the area of the display unit electrically connected thereto in the current state of the art. Of course, with the development of level of technology, when the PPI is greater than or equal to 530, the above structure should be also achieved. Therefore, the PPI is not limited in the present invention.

As compared with the AMOLED display panel of the prior art, the AMOLED display panel of the present application reduces an occupied area of the lower edge region of the driving circuit region by keeping an area of the display light-emitting region, and the AMOLED display panel saves a certain space for setting a trace of the fan-out region, so that a width of a lower side frame of the display panel is reduced.

Furthermore, the occupied area of the upper edge region of the driving circuit region is reduced and thus an additional space is used for setting a source driving circuit or the VSS trace. Therefore, a width of an upper side frame of the display panel is reduced. Reducing area of two side edge regions of the driving circuit region and thus an additional space is used for setting a gate driving circuit or the VSS trace, and a width of frames of two sides of the display panel is reduced. Accordingly, a technical problem of the large width of the lower side frame of the existing AMOLED display panel is solved.

### BRIEF DESCRIPTION OF DRAWINGS

In order to more clearly illustrate the embodiments of the present application or the technical solutions in the prior art, the drawings used in the embodiments will be briefly described below. The drawings in the following description are only partial embodiments of the present application, and those skilled in the art can obtain other drawings according to the drawings without any creative work.

FIG. 1 is a schematic structural view of an active matrix organic light-emitting diode (AMOLED) display panel of prior art.

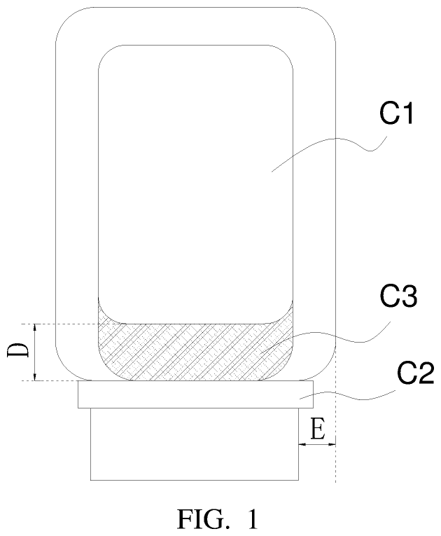

FIG. 2 is a schematic structural view of a driving unit and a display unit of the prior art.

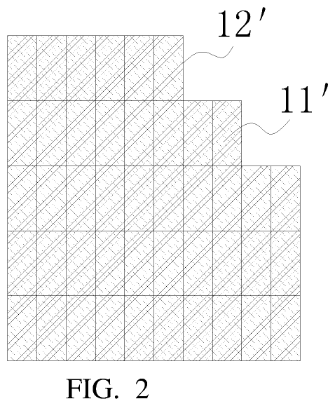

FIG. 3 is a schematic structural view of an AMOLED display panel according to a first embodiment of the present invention.

FIG. 4 is an enlarged view of A in FIG. 3.

FIG. 5 is an enlarged view of B in FIG. 3.

FIG. 6 is a schematic cross-sectional view of the AMOLED display panel showing an intermediate region, a driving unit disposed in the lower edge region, and a corresponding display unit according to the first embodiment of the present invention.

FIG. 7 is a schematic cross-sectional view of the AMOLED display panel showing an intermediate region, a driving unit disposed in the lower edge region, and a corresponding display unit according to a second embodiment of the present invention.

FIG. 8 is a schematic structural view of AMOLED display panel showing an arrangement of a driving unit and a display unit according to a third embodiment of the present invention.

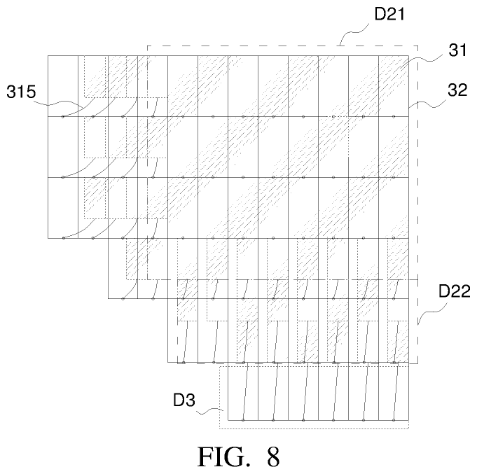

FIG. 9 is a schematic cross-sectional view of the AMOLED display panel showing an intermediate region, a driving unit disposed in the lower edge region, and a corresponding display unit according to a third embodiment of the present invention.

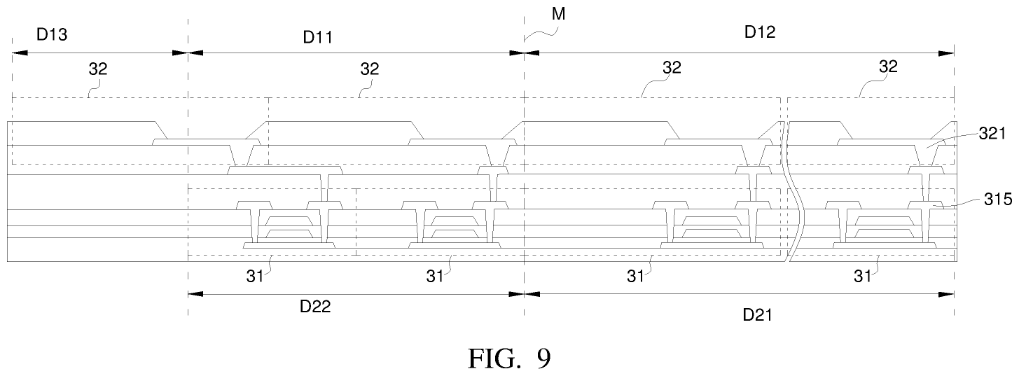

### DETAILED DESCRIPTION OF PREFERRED EMBODIMENTS

Please refer to the drawings in the drawings, in which the same reference numerals represent the same components. The following description is based on the specific embodiments of the present invention as illustrated, and should not be construed as limiting the specific embodiments that are not described herein.

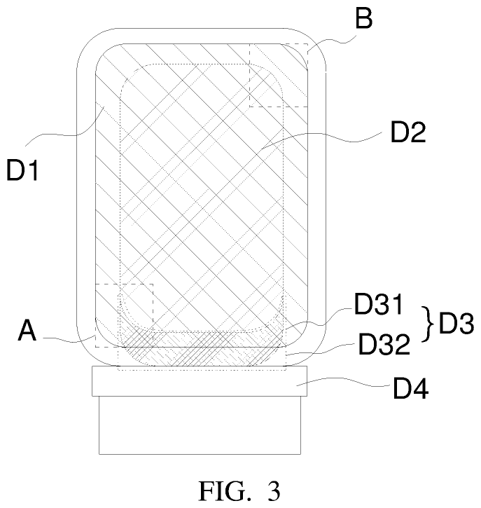

Referring to FIG. 3, FIG. 3 is a schematic structural view of an AMOLED display panel according to a first embodiment of the present invention.

According to a first embodiment of the present invention, the AMOLED display panel comprises a driving circuit region D2 for driving a display light-emitting region D1 to emit light, a fan-out region D3 for setting a fanout trace, the display light-emitting region D1 disposed above the driving circuit region D2 and the fan-out region D3, and a bending region D4 for bending.

An area of the driving circuit region D2 is less than an area of the display light-emitting region D1, and the display light-emitting region D1 completely covers the driving circuit region D2 and at least a portion of the fan-out region D3.

According to the first embodiment of the present invention, an area of a lower edge region of the driving circuit region D2 is reduced by keeping an area of the display light-emitting region D1, and a certain space is saved for setting a trace of the fan-out region D3, so that a width of a lower side frame of the display panel is reduced.

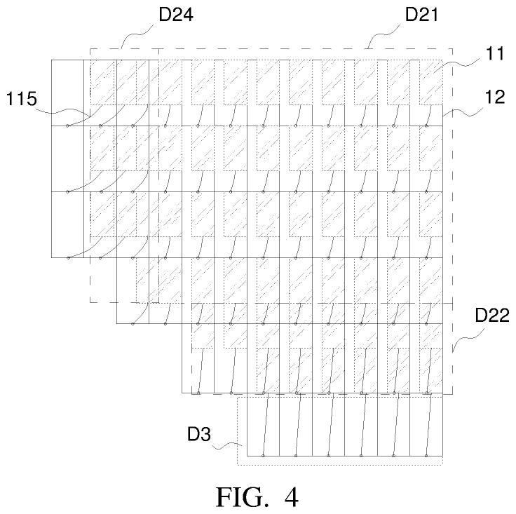

Specifically, referring to FIG. 4, the driving circuit region D2 comprises a plurality of driving units 1, the display light-emitting region D1 comprises a plurality of display units 12, each of the driving units 11 is electrically connected to one of the display units 12, and an area of each of the driving units 11 is less than an area of each of the display units 12, and an area of the circuit region D2 is maximally compressed.

The driving circuit region D2 comprises an intermediate region D21 and a lower edge region D22 disposed below the intermediate region D21, and a distance between each two of the driving units 11 disposed in the intermediate region D21 is greater than a distance between each two of the driving units 11 disposed in the lower edge region D22, so that the area of the lower edge region D22 is reduced.

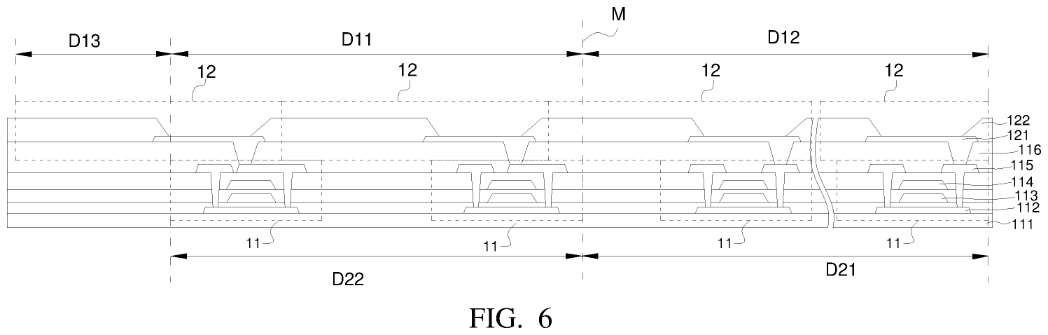

In the first embodiment of the present invention, the area of the display light-emitting area D1 is a sum of areas of orthographic projections of the plurality of display units 12 on the substrate 111. The area of single display unit 12 is a sum of areas of orthographic projections of an opening of a pixel defining layer and a partial pixel defining layer disposed at one side of the opening on the substrate 111 (as shown in FIG. 6). The area of the driving circuit region D2 is a sum of the areas of the orthographic projections of the plurality of driving units 11 on the substrate 111. The area of single driving unit 11 is an area occupied by the layout of a sub-pixel circuit, such as a sum of areas of the orthographic projections of 7T1C and 6T1C on the substrate. That is, the area of the single driving unit 11 is a sum of the areas of the orthographic projections of the 7T1C and 6T1C on the substrate. However, there is merely one driving thin film transistor shown in the embodiment of the present invention, and the area of the single driving unit comprises the driving thin film transistor and at least one switched thin film transistor that are well known to those skilled persons in the art and will not be described again. Each of the driving units 11 comprises a driving thin film transistor used for driving the display unit 12 to emit light and at least one switching thin film transistor (not shown) functioning as a switch.

The size of the driving unit 11 and the display unit 12 are designed differently, and the display unit 12 is designed according to the original panel size and resolution in the prior art, and the area of the driving unit 11 is reduced. That is, the area of the driving unit 11 is less than the area of the display unit 12.

In addition, the arrangement distance of the driving unit 11 of the lower edge region D22 is reduced, so that an occupied area of the lower edge region D22 is reduced. Therefore, a certain space is saved for setting a trace of the fan-out region D3, and a width of a lower side frame of the display panel is reduced.

Each of the driving units 11 comprises the driving thin film transistor. The driving thin film transistor comprises a source/drain 115 and a planar layer 116 disposed on the source/drain 115. Each of the display units 12 comprises an anode 121 disposed on the planar layer 116 and a pixel defining layer 122 disposed on the anode 121, and the pixel defining layer 122 is provided with an opening. The source/drain 115 is electrically connected to the anode 121.

The display light-emitting region D1 comprises a first display light-emitting region D11 corresponding to the lower edge region D22, a second display light-emitting region D12 corresponding to the intermediate region D21, and a third display light-emitting region D13 corresponding to the fan-out region D3. At least one of the driving units 11 disposed in the lower edge region D22 is electrically connected to at least one the display unit 12 disposed in the third display light-emitting region D13.

The lower edge region D22 includes a first edge M, and the first edge M is disposed at a side of the lower edge region D22 close to the intermediate region D21.

One of the driving units 11 is disposed in the lower edge region D22 and one of the display units 12 is electrically connected to the one of driving units 11 disposed in the lower edge region and located near the first edge M. The source/drain 115 of each of the driving units 11 is closer to the first edge M in relative to the anode 121 of each of the display units. Therefore, there is no driving unit below the third display light-emitting region D13, so that it is used for setting a trace of the fan-out region D3.

The above arrangement can reduce the area of the lower edge region D22, so that the width of the lower side frame of the display panel is reduced.

In addition, a distance between the source/drain 115 of each of the driving units 11 and each of the anodes 121 in the lower edge region is larger from a side near the first edge M to another side away from the first edge M. Therefore, it can maximize an area of the third display light-emitting region D13, so that fan-out traces can be disposed below the third display light-emitting region D13 and a number of the fan-out traces be maximized.

The fan-out region D3 is disposed at one side of the lower edge region D22, and the fan-out region D3 comprises a first portion D31 covered by the display light-emitting region D1 and a second portion D32 disposed outside the display light-emitting region D1. That is, the third display light-emitting region D13 is correspondingly disposed above the first portion D31 of the fan-out region D3.

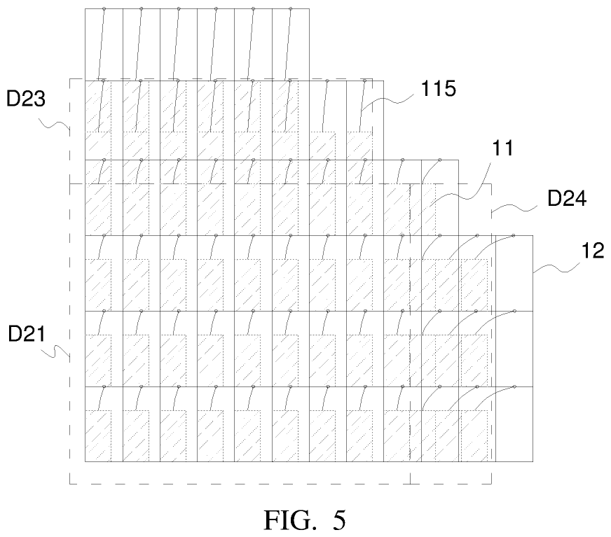

Furthermore, referring to FIG. 5, the driving circuit region D2 further comprises an upper edge region D23 disposed above the intermediate region D21, and a distance between each two of the driving units 11 disposed in the intermediate region D21 is greater than a distance between each two of the driving units 11 disposed at the upper edge region D23. Therefore, an occupied area of the upper edge area D23 is reduced.

The arrangement distance of the driving units 11 disposed in the upper edge region D23 is reduced. That is, in the vertical space, the driving units 11 disposed in the upper edge region D22 and the display units 12 which correspond to the driving units 11 are dislocated, and the driving units 11 disposed in the upper edge region D23 are close to the intermediate region D21, so that the occupied area of the upper edge area D23 is reduced. Therefore, an additional space is used for arranging a source driving circuit or a VSS trace, and the width of the upper side frame of the display panel is reduced.

Furthermore, referring to FIG. 4 and FIG. 5, the driving circuit region D2 comprises two side edge regions D24 disposed at both sides of the intermediate region D21, and a distance between each two of the driving units 11 disposed in the intermediate region D21 is greater than a distance between each two of the driving units 11 disposed at each of the two side edge regions D24. Therefore, an occupied area of the two side edge regions D24 is reduced.

The arrangement distance of the driving units 11 disposed at two side edge regions of the driving circuit region D2. That is, in the vertical space, the driving units 11 disposed at two side edge regions D24 and the display units 12 which correspond to the driving units 11 are dislocated, and the driving units 11 disposed at two side edge regions D24 are close to the intermediate region D21, so that the occupied areas of the two side edge regions D24 are reduced. Therefore, an additional space is used for arranging the gate driving circuit or the VSS trace, and a width of two side frame of the display panel is reduced.

In addition, in one embodiment of the present invention, the distance between each two of the driving units disposed in the intermediate region D21 is not necessarily equal. For example, the distance between each two of the driving units disposed in the intermediate region D21 can also be gradually reduced from a center to a peripheral edge. Therefore, an occupied area of the drive circuit region D2 is further reduced.

Referring to FIG. 6, in the first embodiment of the present invention, each of the driving thin film transistors comprises the substrate 111, an active layer 112 disposed on the substrate 111, a first gate 113 disposed on the active layer 112, a second gate 114 disposed on the first gate 113, the source/drain 115 disposed on the second gate 114, and the planar layer 116 disposed on the source/drain 115. A first insulating layer is disposed between the active layer 112 and the first gate 113. A second insulating layer is disposed between the first gate 113 and the second gate 114. An interlayer dielectric layer is disposed between the second gate 114 and the source/drain 115.

Each of the display units 12 comprises the anode 121 disposed on the planar layer 116, the pixel defining layer 122 disposed on the anode 121, and an organic light-emitting layer (not shown).

The trace of the fan-out region D3 and the first gate 113, the second gate 114 or the source/drain 115 are disposed on the same layer. The trace of the fan-out region D3 extends outward from the lower edge region of the driving circuit region D2.

In the first embodiment of the present invention, the driving units 11 disposed in the peripheral edge region of the driving circuit region D2 and the display units 12 which are electrically connected to the driving units 11 are dislocated. That is, the source/drain 115 of each of the driving units 11 is dislocated in relative to the anode 121 near one side the first edge M, which results each of the driving units 11 not to be completely below the corresponding each of the display units 12. When a space between the source/drain 115 is enough, a length of the source/drain 115 can be appropriately extended below the anode 121. The driving units 11 disposed in the peripheral edge regions (upper, lower, and both side edge regions) of the driving circuit region D2 are electrically connected to the display units 12 through via holes.

A length of the source/drain 115 of each of the driving units 11 electrically connected to the anode 121 of each of the display units 12 disposed in the lower edge region D21 is longer from a side near the first edge M to another side away from the first edge M.

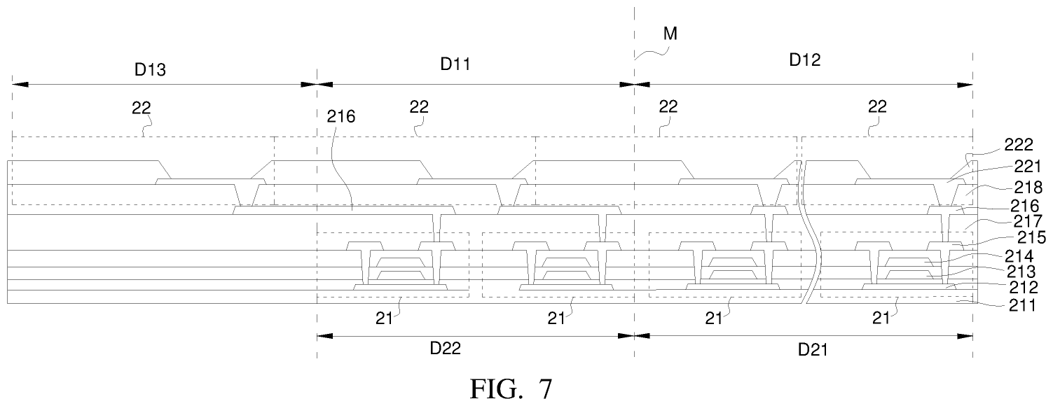

Referring to FIG. 7, in a second embodiment of the present invention, the display light-emitting region D1 comprises the first display light-emitting region D11 corresponding to the lower edge region D22, the second display light-emitting region D12 corresponding to the intermediate region D21, and the third display light-emitting region D13 corresponding to the fan-out region D3. Each of the driving units 21 comprises the driving thin film transistor. The difference between the second embodiment and the first embodiment of the present invention is that the thin film transistor further comprises a substrate 211, an active layer 212 disposed on the substrate 211, a first gate 213 disposed on the active layer 212, a second gate 214 disposed on the first gate 213, the source/drain 215 disposed on the second gate 214, and a planar layer 217 disposed on the source/drain 215. A source/drain trace 216 is disposed on the planar layer 217. A first insulating layer is disposed between the active layer 212 and the first gate 213. A second insulating layer is disposed between the first gate 213 and the second gate 214. An interlayer dielectric layer is disposed between the second gate 214 and the source/drain 215. Another planar layer 218 is disposed between the source/drain 215 and the source/drain trace 216.

Each of the display units 22 comprises an anode 221 disposed on the planar layer 218, a pixel defining layer 222 disposed on the anode 221, and an organic light-emitting layer (not shown).

The source/drain 215 of the driving thin film transistor is electrically connected to the anode 221 which corresponds to the display unit 22 through the source/drain trace 216.

In the second embodiment of the present invention, the driving units 21 disposed in the peripheral edge region of the driving circuit region and the display units 22 which correspond to the driving units 21 are dislocated. That is, the source/drain 215 of each of the driving units 21 is dislocated in relative to the anode 221 near one side the first edge M, which results each of the driving units 21 not to be completely below the corresponding each of the display units 22. When a space between the source/drain 215 is not enough, the driving units 21 disposed in the peripheral edge regions (upper, lower, and both side edge regions) of the driving circuit region are electrically connected to the display units 22 through the source/drain traces 216.

A length of the source/drain 216 of each of the driving unit 21 electrically connected to the anode 221 of each of the display units 22 disposed in the lower edge region D21 is longer from a side near the first edge M to another side away from the first edge M.

The driving circuit region comprises the intermediate region D21 and the lower edge region D22 disposed below the intermediate region D21. In the intermediate region D21, an area of each of driving units 31 is equal to an area of each of display units 32. In the lower edge region D22, the area of each of the driving units 31 is less than an area of each of the display units 32.

The display light-emitting region D1 comprises the first display light-emitting region D11 corresponding to the lower edge region D22, the second display light-emitting region D12 corresponding to the intermediate region D21, and the third display light-emitting region D13 corresponding to the fan-out region D3. At least part of the driving unit 31 disposed in the lower edge region D22 is electrically connected to the display unit 32 disposed in the third display light-emitting region D13.

The lower edge region D22 includes the first edge M. The first edge M is disposed at a side of the lower edge region D22 close to the intermediate region D21.

Each of the driving units 31 is disposed in the lower edge region D22 and each of the display units 32 disposed in the lower edge region D22 is electrically connected to the each of the driving units 31. A source/drain 315 of each of the driving units 31 is dislocated in relative to the anode 321 near one side the first edge M. A space below the third display light-emitting region D13 is used for setting a trace of the fan-out region D3. Therefore, an occupied area of the lower edge region D22 is reduced so as to set the trace of the fan-out region D3.

The fan-out region is disposed at one side of the lower edge region D22, and the fan-out region D3 comprises a first portion covered by the display light-emitting region and a second portion disposed outside the display light-emitting region.

As compared with the AMOLED display panel of the prior art, the AMOLED display panel of the present application reduces the occupied area of the lower edge region of the driving circuit region by keeping an area of the display light-emitting region, and the AMOLED display panel saves a certain space for setting a trace of the fan-out region, so that a width of a lower side frame of the display panel is reduced.

Furthermore, the occupied area of the upper edge region of the driving circuit region is reduced and thus an additional space is used for setting the source driving circuit or the VSS trace. Therefore, a width of an upper side frame of the display panel is reduced. Reducing area of two side edge regions of the driving circuit region and thus an additional space is used for setting a gate driving circuit or the VSS trace, and a width of frames of two sides of the display panel is reduced. Accordingly, a technical problem of the large width of the lower side frame of the existing AMOLED display panel is solved.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. An active-matrix organic light-emitting diode (AMOLED) display panel, comprising:
a driving circuit region for driving a display light-emitting region to emit light;
a fan-out region for setting a fanout trace; and
a display light-emitting region disposed above the driving circuit region and the fan-out region;
wherein an area of the driving circuit region is less than an area of the display light-emitting region, and the display light-emitting region completely covers the driving circuit region and at least a portion of the fan-out region;
the driving circuit region comprises a plurality of driving units, the display light-emitting region comprises a plurality of display units, each of the driving units is electrically connected to one of the display units, and an area of each of the driving units is less than an area of each of the display units;
the driving circuit region comprises an intermediate region and a lower edge region disposed below the intermediate region, and a distance between each two of the driving units disposed in the intermediate region is greater than a distance between each two of the driving units disposed in the lower edge region;
the display light-emitting region comprises a first display light-emitting region corresponding to the lower edge region and a third display light-emitting region corresponding to the fan-out region, and at least a portion of the driving units is electrically connected to the display units disposed in the third display light-emitting region; and
the fan-out region is disposed at one side of the lower edge region, and the fan-out region comprises a first portion covered by the display light-emitting region and a second portion disposed outside the display light-emitting region.

2. The AMOLED display panel according to claim 1, wherein each of the driving units comprises a driving thin film transistor for driving the display units to emit light, and the driving thin film transistor comprises a source/drain and a planar layer disposed on the source/drain;
each of the display units comprises an anode disposed on the planar layer and a pixel defining layer disposed on the anode, and the pixel defining layer is provided with an opening;
the source/drain is electrically connected to the anode;
the lower edge region comprises a first edge, and the first edge is disposed at a side of the lower edge region close to the intermediate region; and
in one of the driving units disposed in the lower edge region and in one of the display units which is electrically connected to each of the driving units disposed in the lower edge region and located near the first edge, the source/drain of each of the driving units is closer to the first edge in relative to the anode of the one of the display units.

3. The AMOLED display panel according to claim 2, wherein a distance between the source/drain of each of the driving units and the anode in the lower region is larger from a side near the first edge to another side away from the first edge.

4. The AMOLED display panel according to claim 2, wherein a length of the source/drain of each of the driving units electrically connected to the anode of the display unit disposed in the lower edge region is longer from a side near the first edge to another side away from the first edge.

5. The AMOLED display panel according to claim 4, wherein each of the driving thin film transistors comprises a substrate, an active layer disposed on the substrate, a first gate disposed on the active layer, a second gate disposed on the first gate, the source/drain disposed on the second gate, and the planar layer disposed on the source/drain; and
the source/drain of the driving thin film transistor is electrically connected to the anode corresponding to the display unit through a via hole.

6. The AMOLED display panel according to claim 2, wherein each of the driving thin film transistors comprises a substrate, an active layer disposed on the substrate, a first gate disposed on the active layer, a second gate disposed on the first gate, the source/drain disposed on the second gate, the planar layer disposed on the source/drain, and a source/drain trace disposed on the planar layer;
the source/drain of the driving thin film transistor is electrically connected to the anode of the corresponding display unit through the source/drain trace; and
a length of the source/drain trace of another one of the driving units electrically connected to the anode of another one of the display units disposed in the lower edge region and away from the first edge is longer than a length of the source/drain trace of the one of the driving units near the first edge.

7. The AMOLED display panel according to claim 1, wherein the driving circuit region further comprises two side edge regions disposed at both sides of the intermediate region, and a distance between each two of the driving units disposed in the intermediate region is greater than a distance between each two the driving units disposed at each of the two side edge regions.

8. An active-matrix organic light-emitting diode (AMOLED) display panel, comprising:
a driving circuit region for driving a display light-emitting region to emit light;
a fan-out region for setting a fanout trace; and
a display light-emitting region disposed above the driving circuit region and the fan-out region;
wherein an area of the driving circuit region is less than an area of the display light-emitting region, and the display light-emitting region completely covers the driving circuit region and at least a portion of the fan-out region.

9. The AMOLED display panel according to claim 8, wherein the driving circuit region comprises a plurality of driving units, the display light-emitting region comprises a plurality of display units, each of the driving units is electrically connected to one of the display units, and an area of each of the driving units is less than an area of each of the display units.

10. The AMOLED display panel according to claim 8, wherein the driving circuit region comprises a plurality of driving units, the display light-emitting region comprises a plurality of display units, each of the driving units is electrically connected to one of the display units; and
the driving circuit region comprises an intermediate region and a lower edge region disposed below the intermediate region, and an area of each of the driving units disposed in the intermediate region is equal to an area of each of the display units disposed in the intermediate region, and an area of each of the driving units disposed in the lower edge region is less than an area of each of the display units disposed in the lower edge region.

11. The AMOLED display panel according to claim 9, wherein the driving circuit region comprises an intermediate region and a lower edge region disposed below the intermediate region, and a distance between each two of the driving units disposed in the intermediate region is greater than a distance between each two of the driving units disposed in the lower edge region.

12. The AMOLED display panel according to claim 11, wherein the display light-emitting region comprises a first display light-emitting region corresponding to the lower edge region and a third display light-emitting region corresponding to the fan-out region, and at least a portion of the driving units is electrically connected to the display units disposed in the third display light-emitting region.

13. The AMOLED display panel according to claim 12, wherein each of the driving units comprises a driving thin film transistor for driving the display units emitting, and the driving thin film transistor comprises a source/drain and a planar layer disposed on the source/drain;
each of the display units comprises an anode disposed on the planar layer and a pixel defining layer disposed on the anode, and the pixel defining layer is provided with an opening;
the source/drain is electrically connected to the anode;
the lower edge region comprises a first edge, and the first edge is disposed at a side of the lower edge region close to the intermediate region; and
one of the driving units is disposed in the lower edge region and one of the display units is electrically connected to the one of driving units disposed in the lower edge region and located near the first edge, the source/drain of each of the driving units is closer to the first edge in relative to the anode of each of the display units.

14. The AMOLED display panel according to claim 13, wherein a distance between the source/drain of each of the driving units and the anode in the lower edge region is larger from a side near the first edge to another side away from the first edge.

15. The AMOLED display panel according to claim 13, wherein a length of the source/drain of each of the driving units electrically connected to the anode of each of the display units disposed in the lower edge region is longer from a side near the first edge to another side away from the first edge.

16. The AMOLED display panel according to claim 15, wherein each of the driving thin film transistors comprises a substrate, an active layer disposed on the substrate, a first gate disposed on the active layer, a second gate disposed on the first gate, the source/drain disposed on the second gate, and the planar layer disposed on the source/drain; and
the source/drain of the driving thin film transistor is electrically connected to the anode of the corresponding display unit through a via hole.

17. The AMOLED display panel according to claim 13, wherein each of the driving thin film transistors comprises a substrate, an active layer disposed on the substrate, a first gate disposed on the active layer, a second gate disposed on the first gate, the source/drain disposed on the second gate, the planar layer disposed on the source/drain, and a source/drain trace is disposed on the planar layer,
the source/drain of the driving thin film transistor is electrically connected to the anode of the corresponding to the display unit through the source/drain trace; and
a length of the source/drain trace of another one of the driving units electrically connected to the anode of another one of the display units disposed in the lower edge region and away from the first edge is longer than a length of the source/drain trace of the one of the driving units near the first edge.

18. The AMOLED display panel according to claim 11, wherein the fan-out region is disposed at one side of the lower edge region, and the fan-out region comprises a first portion covered by the display light-emitting region and a second portion disposed outside the display light-emitting region.

19. The AMOLED display panel according to claim 11, wherein the driving circuit region further comprises two side edge regions disposed at both sides of the intermediate region, and a distance between each two of the driving units disposed in the intermediate region is greater than a distance between each two of the driving units disposed at the two side edge regions.

20. The AMOLED display panel according to claim 11, wherein the driving circuit region further comprises an upper edge region disposed above the intermediate region, and a distance between each two of the driving units disposed in the intermediate region is greater than a distance between each two of the driving units disposed at the upper edge region.
